(19) United States
(12) Patent Application Publication
(10) Pub. No.: US 2026/0088259 A1
(43) Pub. Date: Mar. 26, 2026

(54) DOME SHAPED CHAMBER FOR GENERATING IN-SITU CLEANING PLASMA

(71) Applicant: Kyle Watt HART

(72) Inventor: Kyle Watt HART

(21) Appl. No.: 19/108,672

(22) PCT Filed: Sep. 20, 2023
(86) PCT No.: PCT/US2023/033198

§ 371 Date: Mar. 4, 2025

(51) Int. Cl. H01J 37/32

(52) U.S. Cl. CPC H01J 37/32477; H01J 37/3211; H01J 37/3244; H01J 37/32633; H01J 37/32724; H01J 37/32862; H01J 2237/335

(57) ABSTRACT

A processing chamber includes a first portion, including a dome, and a second portion. The dome includes a ceramic material and is elliptical in shape. A pedestal to process a substrate is arranged in the second portion. A showerhead is arranged at a base of the dome between the first and second portions. An injector including the ceramic material is mounted on the dome to inject a process gas and a cleaning gas into the dome during substrate processing and cleaning of the processing chamber, respectively. A coil is disposed around a portion of the dome. An RF generator supplies RF power to the coil to generate plasma in the dome during the substrate processing and the cleaning. A controller controls temperatures of the pedestal and the showerhead at respective predetermined temperatures within a predetermined range during the substrate processing and the cleaning.

### CROSS-REFERENCE TO RELATED APPLICATIONS

This application claims the benefit of U.S. Provisional Application No. 63/412,152, filed on Sep. 30, 2022. The entire disclosure of the application referenced above is incorporated herein by reference.

### FIELD

The present disclosure relates generally to substrate processing systems and more particularly to a dome-shaped chamber for generating in-situ cleaning plasma.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems typically comprise one or more processing chambers. Each processing chamber encloses a pedestal on which a substrate such as a semiconductor wafer is arranged during processing. A gas delivery system may be used to introduce a process gas mixture comprising one or more precursors into the processing chamber to deposit a film on the substrate or to etch the substrate. Plasma may be struck in the processing chamber.

Some substrate processing systems use an atomic layer deposition (ALD) process to deposit material on substrates. ALD is a thin-film deposition method that sequentially performs a chemical process to deposit a thin film on a surface of a substrate. ALD uses at least two chemicals called precursors (reactants) that react with the surface of the substrate one precursor at a time in a sequential, self-limiting manner. Through repeated exposure to separate precursors, a thin film is gradually deposited on the surface of the substrate.

### SUMMARY

A substrate processing system comprises a processing chamber, a pedestal, a showerhead, an injector, a coil, a radio frequency (RF) generator, and a controller. The processing chamber comprises a first portion and a second portion. The first portion comprises a dome. The dome comprises a ceramic material and is elliptical in shape. The pedestal is configured to process a substrate arranged in the second portion of the processing chamber. The showerhead is arranged at a base of the dome between the first and second portions of the processing chamber. The injector comprises the ceramic material mounted on the dome. The injector is configured to inject a process gas and a cleaning gas into the dome during substrate processing and cleaning of the processing chamber, respectively. The coil is disposed around a portion of the dome. The RF generator is configured to supply RF power to the coil to generate plasma in the dome during the substrate processing and the cleaning of the processing chamber. The controller is configured to control temperatures of the pedestal and the showerhead at respective predetermined temperatures within a predetermined range during the substrate processing and the cleaning of the processing chamber.

In an addition feature, the predetermined range is 0-1% of the respective predetermined temperatures.

In an addition feature, the controller is configured to maintain the temperatures of the pedestal and the showerhead unchanged at the respective predetermined temperatures during the substrate processing and the cleaning of the processing chamber.

In an addition feature, the ceramic material is alumina.

In an addition feature, inner walls of the dome are coated with a second material that is resistant to heat and corrosion.

In an addition feature, the second material is yttria.

In addition features, the substrate processing system further comprises an enclosure that is arranged around the dome and the coil and that is attached to a periphery of the showerhead. The enclosure comprises a plurality of fans arranged azimuthally symmetrically along sidewalls of the enclosure.

In an addition feature, the substrate processing system further comprises a gas delivery system configured to supply the cleaning gas through the injector at a rate that suppresses particles ejected from the pedestal from contaminating the showerhead during the cleaning of the processing chamber.

In an addition feature, the substrate processing system further comprises a gas delivery system configured to supply an inert gas directly to the showerhead to suppress particles ejected from the pedestal from contaminating the showerhead during the cleaning of the processing chamber.

In an addition feature, the substrate processing system further comprises a gas delivery system configured to supply an inert gas directly to the showerhead to prevent the cleaning gas from stagnating in the showerhead after the cleaning of the processing chamber.

In addition features, the substrate processing system further comprises a gas delivery system. The showerhead comprises a first plenum and a second plenum. The first plenum is configured to filter ions and pass radicals from the plasma to the second portion of the processing chamber. The second plenum is configured to (i) directly receive a precursor from the gas delivery system and supply the precursor to the second portion of the processing chamber during the substrate processing and (ii) directly receive an inert gas from the gas delivery system during the cleaning of the processing chamber.

In an addition feature, the coil comprises a number of turns. The number of turns and locations of the turns around the dome distribute ions and thermal load from the plasma throughout the dome.

In addition features, the pedestal comprises a heater. The substrate processing system further comprises a fluid delivery system configured to supply a coolant to the pedestal and the showerhead. The controller is configured to control the heater and flow of the coolant to maintain the temperatures of the showerhead and the pedestal within the predetermined range of the respective predetermined temperatures during the substrate processing and the cleaning of the processing chamber.

In addition features, the pedestal comprises a heater. The substrate processing system further comprises a fluid delivery system configured to supply a coolant to the pedestal and the showerhead. The controller is configured to control the heater and flow of the coolant to maintain the temperatures of the pedestal and the showerhead unchanged at the respective predetermined temperatures during the substrate processing and the cleaning of the processing chamber.

In still other features, a method of cleaning a processing chamber comprising a pedestal and a showerhead configured to process a substrate comprises controlling, during the cleaning of the processing chamber, temperatures of the pedestal and the showerhead within a predetermined range of respective predetermined temperatures used during processing of the substrate. The method comprises supplying a cleaning gas into an elliptical dome of the processing chamber though an injector mounted on the elliptical dome, the elliptical dome and the injector comprising a ceramic material. The method comprises generating a plasma in the elliptical dome by supplying radio frequency (RF) power to a coil disposed around the elliptical dome. The method comprises controlling flow of the cleaning gas through the injector to suppress contamination of the showerhead due to particles ejected from the pedestal.

In an addition feature, the predetermined range is 0-1% of the respective predetermined temperatures.

In an addition feature, the method further comprises maintaining the temperatures of the pedestal and the showerhead unchanged at the respective predetermined temperatures during the processing of the substrate and the cleaning of the processing chamber.

In an addition feature, the method further comprises spray coating inner walls of the elliptical dome with a second material that is resistant to heat and corrosion.

In an addition feature, the ceramic material is alumina and the second material is yttria.

In addition features, the method further comprises enclosing the elliptical dome and the coil in an enclosure attached to a periphery of the showerhead, and cooling the elliptical dome using a plurality of fans arranged azimuthally symmetrically along sidewalls of the enclosure.

In an addition feature, the method further comprises supplying an inert gas directly to the showerhead to further suppress the contamination of the showerhead due to the particles.

In an addition feature, the method further comprises flowing an inert gas through the showerhead to prevent the cleaning gas from stagnating in the showerhead.

In an addition feature, the method further comprises arranging turns of the coil around the elliptical dome to distribute ions and thermal load from the plasma throughout the elliptical dome.

In addition features, the method further comprises, after the cleaning of the processing chamber, stopping supply of the cleaning gas and the RF power, controlling the temperatures of the pedestal and the showerhead within the predetermined range of the respective predetermined temperatures, and supplying a process gas into the elliptical dome though the injector to process a second substrate in the processing chamber.

In an addition feature, the method further comprises supplying a precursor directly to the showerhead.

In addition features, the method further comprises striking a second plasma in the elliptical dome by supplying the RF power to the coil, and filtering ions and passing radicals from the second plasma to the second substrate.

In an addition feature, the method further comprises supplying a coolant through the pedestal and the showerhead to maintain the temperatures of the showerhead and the pedestal within the predetermined range of the respective predetermined temperatures during the processing of the second substrate in the processing chamber.

In an addition feature, the method further comprises supplying a coolant through the pedestal and the showerhead to maintain the temperatures of the pedestal and the showerhead unchanged at the respective predetermined temperatures during the processing of the second substrate in the processing chamber.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising a dome shaped processing chamber utilized to generate in-situ cleaning plasma during substrate processing and chamber cleaning according to the present disclosure;

FIG. 2 schematically shows an example of an enclosure that comprises cooling fans and that encloses the dome of the processing chamber of the substrate processing system of FIG. 1;

FIG. 3 shows an example of a portion of a gas delivery system used in the substrate processing system of FIG. 1 in further detail; and

FIG. 4 shows a flowchart of a method of processing substrates and cleaning the processing chamber of FIG. 1 using the in-situ cleaning plasma while keeping pedestal and showerhead temperatures unchanged during substrate processing and cleaning.

In the drawings, reference numbers may be reused to identify similar and/or identical elements.

### DETAILED DESCRIPTION

Some substrate processing systems (also called tools) comprise up to four processing chambers that are used to deposit materials on substrates using a deposition process. The processing chambers are periodically cleaned using a cleaning process during which substrate production is suspended. That is, the cleaning process is performed separately and distinctly from the deposition process. For example, the cleaning process is typically performed after many cycles of the deposition process during a preventive maintenance procedure that is periodically performed to clean the processing chambers and components thereof.

In a typical cleaning process used to clean the processing chambers, a cleaning plasma is generated using a remote plasma source (RPS) arranged external to the processing chambers. For example, the RPS is located centrally between the processing chambers and the cleaning plasma from the RPS is supplied to each processing chamber to clean the processing chambers. Using the externally generated cleaning plasma to clean multiple processing chambers presents various problems.

For example, several components of the processing chamber such as the showerhead and the pedestal need to be set to different temperatures for the cleaning process than for the deposition process used to process substrates in the processing chamber. For example, the temperatures of the showerhead and the pedestal are typically maintained at 50 and 550 degrees Celsius, respectively. These temperatures may differ depending on the process (e.g., recipe) used to process substrates in the processing chamber. The temperatures of the showerhead and the pedestal are typically maintained at 150 and 400 degrees Celsius, respectively during the cleaning process.

Typically, before performing the cleaning process, the pedestal temperatures are reduced below the temperatures used during substrate processing (e.g., from 550 to 400 degrees Celsius) because at higher temperatures (e.g., above 450 degrees Celsius), the pedestals can generate particles off the surfaces of the pedestals that contaminate the showerheads. Therefore, to minimize the generation of particles off the surfaces of the pedestals that contaminate the showerheads, before performing the cleaning process, the pedestal temperatures are typically reduced below the temperatures used during substrate processing (e.g., from 550 to 400 degrees Celsius).

After the cleaning process, the showerhead temperatures are decreased (e.g., from 150 to 50 degrees Celsius) and the pedestal temperatures are increased (e.g., from 400 to 550 degrees Celsius). The different temperature settings used during substrate processing and the cleaning process require additional time to allow the temperatures of the components to transition between the temperatures required for the deposition process and the temperatures required for the cleaning process. The additional time required for these temperature transitions to occur reduces the production time of the processing chambers.

Furthermore, the contamination problem is exacerbated because the cleaning plasma is supplied at a location of the processing chambers that is between the showerhead and the pedestal. Due to the location where the cleaning plasma is supplied and due to the typical conical shape of the plasma chambers, the particles generated off the surfaces of the pedestals are transported towards the showerheads and contaminate the showerheads.

In addition, the movement of the remote cleaning plasma in the processing chamber is such that the cleaning process takes longer time to clean the showerheads and yet does not clean the showerheads effectively (i.e., the etch rate at the showerheads is less than that at the pedestals). Thus, the cleaning process that uses the remote cleaning plasma exacerbates the particle contamination of the showerheads that occurs during the cleaning process. Accordingly, the showerheads need to undergo a requalification process following the cleaning process before the deposition process can be resumed in the processing chambers. The requalification process, which is performed on all four processing chambers of the tool, further reduces the production time of the processing chambers.

The present disclosure provides an in-situ plasma-based cleaning process that solves the above problems. The in-situ plasma-based cleaning process of the present disclosure is also performed separately and distinctly from processes such as ALD that are performed for processing substrates in the processing chamber. For example, the cleaning process is typically performed after many cycles of processing substrates in the processing chamber during a preventive maintenance procedure that is periodically performed to clean the processing chambers and components thereof.

Specifically, in the in-situ plasma-based cleaning process, instead of supplying a remotely generated cleaning plasma to the processing chambers, the cleaning plasma is generated in-situ in each processing chamber. Further, the temperatures of the components such as the showerhead and the pedestal are not changed between the cleaning and deposition processes. During the cleaning process, the components are maintained at the same temperatures used during substrate processing. At most, the temperatures of the components may vary within a predetermined range (e.g., a narrow range of 0-1%) between substrate processing and the cleaning process. For practical purposes, the temperatures of the components are considered as unified (i.e., as being substantially equal) during substrate processing and the cleaning process so long as the temperatures are maintained within the predetermined range. Throughout the present disclosure, unifying the temperatures of the components during substrate processing and the cleaning process should be understood as controlling or maintaining the temperatures of the components at respective predetermined temperatures within a predetermined range such as 0-1%. The predetermined range is explained below in detail after the description of FIG. 4. The cleaning process performed using the in-situ plasma generated in each processing chamber provides the following improvements.

The cleaning process performed using the in-situ plasma generated in each processing chamber provides the following improvements. By unifying the temperatures of the components for the cleaning and deposition processes, the time required to transition between different temperature settings typically used for these processes is eliminated. Eliminating the time required for the temperature transition increases the production time of the processing chambers.

Further, the cleaning plasma is generated in each processing chamber using the same hardware that is used to generated plasma during the deposition process. Specifically, during the deposition process, a process gas is supplied through an injector located at the top of the processing chamber and plasma is struck in the processing chamber. During the cleaning process, a cleaning gas is supplied through the same injector located at the top of the processing chamber and the cleaning plasma is struck in the processing chamber. The cleaning plasma first passes through the showerhead and first cleans the showerhead, and then reaches and cleans the pedestal. That is, the etch rate at the showerhead is greater than that at the pedestal. Thus, the in-situ plasma-based cleaning process not only eliminates the remote plasma source but also cleans the showerhead better than when the remote cleaning plasma is used. Since the in-situ cleaning plasma cleans the showerhead better than when the remote cleaning plasma is used, the in-situ cleaning plasma-based cleaning process is also shorter in duration than the remote plasma-based cleaning process.

Furthermore, unifying the temperatures of the components for the cleaning and deposition processes requires that the pedestal is maintained at the same temperature during the cleaning process as during substrate processing (e.g., 550 degrees Celsius). The high pedestal temperature can generate particles off the surfaces of the pedestal that contaminate the showerhead. The in-situ plasma-based cleaning process mitigates (suppresses) the particle contamination of the showerhead by controlling (e.g., increasing) the flow of the cleaning gas through the injector during the cleaning process.

In addition, the cleaning gas tends to stagnate in the showerhead, which can contaminate and damage the showerhead. The stagnation of the cleaning gas in the showerhead can be prevented (i.e., traces of the clean gas can be purged) by flowing an inert gas (called a trickle) supplied directly through the showerhead. Thus, the showerheads need not be requalified after the cleaning process and the deposition process can be resumed for production immediately following the cleaning process. The processing chambers are ready for production immediately following the cleaning process also because the temperatures of the showerhead and the pedestal are not changed (i.e., are unified) between the deposition and cleaning processes. Since the in-situ plasma-based cleaning process eliminates the temperature transition time and mitigates the particle contamination of the showerheads, the duration of the in-situ plasma-based cleaning process is further reduced.

Thus, the in-situ plasma-based cleaning process of the present disclosure eliminates the remote plasma source, cleans the showerheads better than the remote plasma-based cleaning process, eliminates the particle contamination of the showerheads, and increases the production time of the processing chambers than when the remote plasma-based cleaning process is used.

The in-situ plasma-based cleaning process uses a different geometry and material for the dome of the processing chambers in which plasma is struck than the conventional processing chambers that use the remote plasma in the cleaning process. The different geometry (described below in detail) optimizes the movement of plasma during the deposition and cleaning processes. The different material of the dome, along with a coating applied to inner surfaces of the dome, reduces etching and corrosion of the inner surfaces of the dome due to the harsh chemical, thermal, and electrical environments used during the deposition and cleaning processes.

Additionally, the injectors of the processing chambers also comprise a different material than that used for the injectors of the conventional processing chambers that use the remote plasma-based cleaning process. The different material exhibits less etching and corrosion of the injectors due to the harsh environments used during the deposition and cleaning processes. Further, the present disclosure also provides an enclosure with improved cooling for the dome and RF coil disposed around the dome for plasma generation. These and other features of the present disclosure are described below in detail.

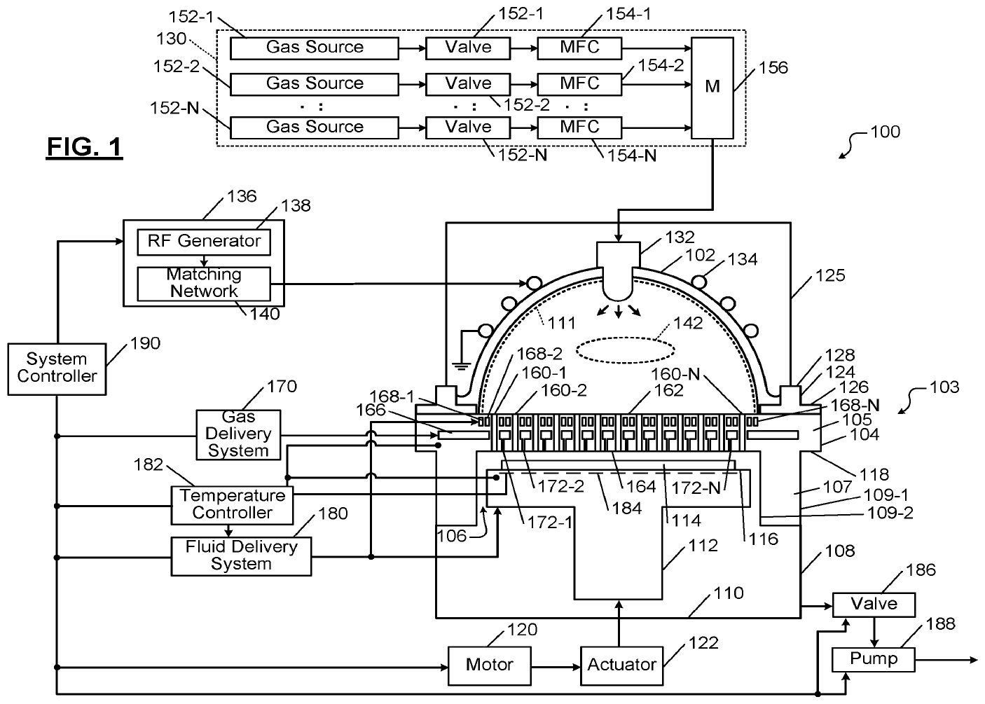

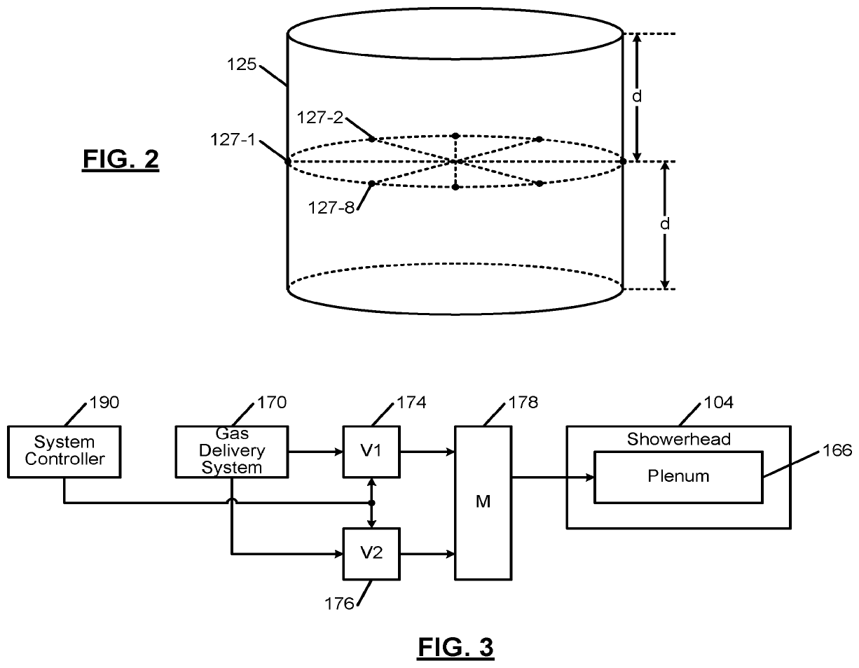

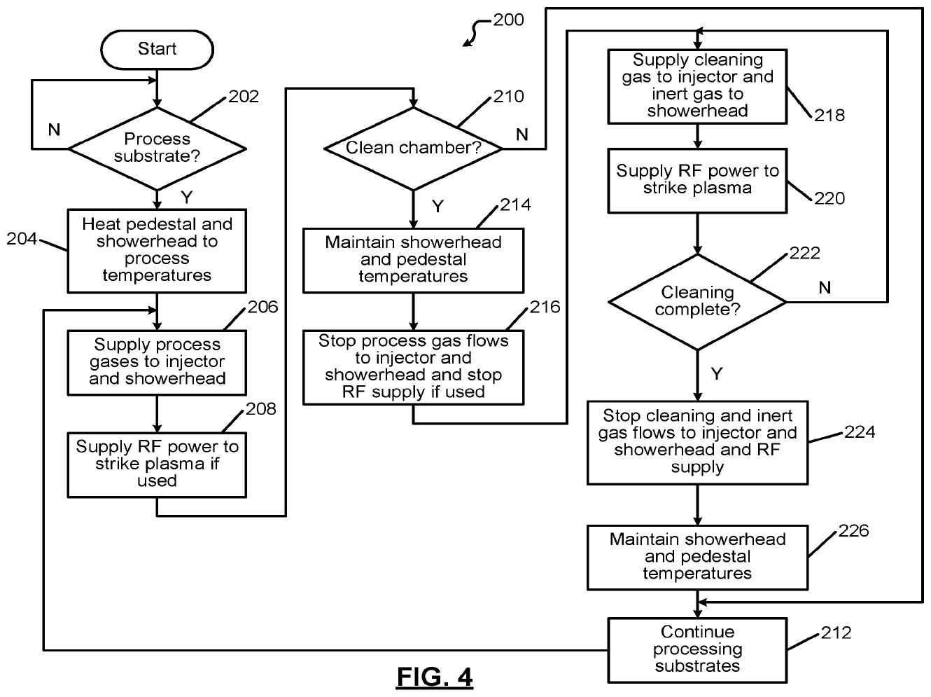

The present disclosure is organized as follows. In Section 1, an example of the substrate processing system 100 comprising the dome shaped processing chamber is shown and described with reference to FIG. 1. In Section 2, designs of the dome, the coil, and the enclosure with fans are described in detail wit reference to FIGS. 1 and 2. In Section 3, controlled supply of cleaning and inert gases to mitigate contamination of the showerhead is described with reference to FIGS. 1 and 3. In Section 4, a method of processing substrates and cleaning the plasma chamber according to the present disclosure is described with reference to FIG. 4.

### SECTION 1: SUBSTRATE PROCESSING SYSTEM

FIG. 1 shows a substrate processing system 100 (also called a tool) according to the present disclosure. The substrate processing system 100 comprises a processing chamber 103. The substrate processing system 100 may comprise multiple (e.g., four) processing chambers (also called stations or process modules) that are similar to the processing chamber 103 and comprise components similar to the components of the processing chamber 103 described below. Some of the components of the substrate processing system 100 described below may be common to the multiple processing chambers of the substrate processing system 100. Example of components of the substrate processing system 100 common to the multiple processing chambers comprise gas delivery systems (elements 10, 170), RF generating system (element 136), fluid delivery system (element 180), temperature controller (182), and system controller (element 190).

The processing chamber 103 comprises a dome 102, a showerhead 104, and a pedestal 112. The dome 102 is described below in detail after describing plasma generation. Briefly, the dome 102 is elliptical in shape. Specifically, the shape of the dome 102 is a portion of an ellipse and has an elliptical profile. The shape of the dome resembles the shape of an ellipse with a bottom portion of the ellipse removed along a horizontal plane. The dome 102 comprises a ceramic material (e.g., alumina). The dome 102 is arranged above the showerhead 104 and is attached to the showerhead 104. The pedestal 112 is arranged under the showerhead 104. The showerhead 104 separates the dome 102 and the pedestal 112.

A space defined by inner walls of the dome 102 and an upper surface of the showerhead 104 may be called an upper portion (or a first portion) of the processing chamber 103. A space defined by a lower substrate facing surface of the showerhead 104 and a sidewall 108 and a bottom wall 110 of the processing chamber 103 may be called a lower portion (or a second portion) of the processing chamber 103. The pedestal 112 is arranged in the lower portion of the processing chamber 103 below the showerhead 104. The showerhead 104 separates the upper and lower portions of the processing chamber 103.

The showerhead 104 is a dual plenum showerhead. The showerhead 104 comprises a metal (e.g., aluminum) or an alloy. The showerhead 104 comprises a planar base portion 105 and a cylindrical portion 107 that extends perpendicularly downward from the base portion 105. The base portion 105 is horizontal and is parallel to the top surface 116 of the pedestal 112 and to the bottom wall 110 of the processing chamber 103. The base portion 105 extends radially outwardly at the top of the cylindrical portion 107. The base portion 105 extends radially outwardly from an outer diameter (OD) of the cylindrical portion 107 forming a flange 118. The flange 118 is fastened to a top plate (not shown) of the processing chamber 103. An O-ring (not shown) may be disposed between the flange 118 and the top plate to form a seal between the showerhead 104 and the top plate. The cylindrical portion 107 has an outer wall 109-1 and an inner wall 109-2. The inner wall 109-2 of the cylindrical portion 107 defines a bore 106 of the showerhead 104. A diameter of the bore 106 is equal to a diameter of the inner wall 109-2 of the cylindrical portion 107 (i.e., an inner diameter or ID of the cylindrical portion 107) of the showerhead 104.

The sidewall 108 of the processing chamber 103 is attached to the bottom of the cylindrical portion 107 of the showerhead 104. The sidewall 108 is perpendicular to the base portion 105 of the showerhead 104 and extends vertically downward from the bottom of the outer wall 109-1 of the cylindrical portion 107 of the showerhead 104. The bottom wall 110 of the processing chamber 103 is parallel to the base portion 105 of the showerhead 104 and perpendicular to the sidewall 108 of the processing chamber 103 and is attached to the sidewall 108 of the processing chamber 103.

During processing, a substrate 114 is arranged on a top surface 116 of the pedestal 112 during processing. The top surface 116 of the pedestal 112 is planar and parallel to the base portion 105 of the showerhead 104 and parallel to the bottom wall 110 of the processing chamber 103. Accordingly, when the substrate 114 is arranged on the top surface 116 of the pedestal 112, the substrate 114 is parallel to the top surface 116 of the pedestal 112, the base portion 105 of the showerhead 104, and the bottom wall 110 of the processing chamber 103. The ID of the cylindrical portion 107 of the showerhead 104 (i.e., the diameter of the inner wall 109-2 of the showerhead 104) is greater than an OD of the top surface 116 of the pedestal 112. The ID of the cylindrical portion 107 of the showerhead 104 (i.e., the diameter of the inner wall 109-2 of the showerhead 104) is also greater than an OD of the substrate 114.

An actuator 120 driven by a motor 122 can move the pedestal 112 vertically up and down relative to the showerhead 104 within the cylindrical portion 107 of the showerhead 104. The dome 102 and the showerhead 104 are fixed relative to the pedestal 112. A gap between a bottom of the base portion 105 of the showerhead 104 and the top surface 116 of the pedestal 112 may be adjusted by vertically moving the pedestal 112 within the cylindrical portion 107 of the showerhead 104. For example, during substrate processing, the gap between the bottom of the base portion 105 of the showerhead 104 and the top surface 116 of the pedestal 112 may be of about 0.2 in., 0.15 in., or 0.11 in. When a cleaning process (described below in detail with reference to FIG. 4) is performed to clean the processing chamber 103, the pedestal 112 may be lowered further below the showerhead 104. During the cleaning process, the gap between the bottom of the base portion 105 of the showerhead 104 and the top surface 116 of the pedestal 112 may be much greater than the gap during substrate processing.

A bottom end of the dome 102 is attached to a periphery of a top end of the showerhead 104 using a cylindrical component 124. Specifically, the bottom end of the dome 102 is attached to a top surface 162 of the base portion 105 of the showerhead 104 using the cylindrical component 124. For example, the cylindrical component 124 comprises a ring having a shape of the letter “T” and comprises a horizontal portion 126 and a vertical portion 128. The horizontal portion 126 has a first end defining an outer rim of the cylindrical component 124 and a second end defining an inner rim of the cylindrical component 124. The first end of the horizontal portion 126 (i.e., the outer rim of the cylindrical component 124) is attached to the periphery of the top surface 162 of the showerhead 104 using fasteners (not shown). An outer wall of the dome 102 is attached to the vertical portion 128 along an inner diameter of the vertical portion 128. An inner wall of the dome 102 extends downwards past the second end of the horizontal portion 126. The inner wall of the dome 102 is attached to the top surface 162 of the base portion 105 of the showerhead 104 near the second end of horizontal portion 126 (i.e., near the inner rim of the cylindrical component 124).

The dome 102 generates plasma (specifically, inductively coupled plasma or ICP) in the upper portion of the processing chamber 103 as follows. The dome 102 receives one or more gases from a gas distribution system 130 via a gas injector 132 mounted at the top of the dome 102. For example, as explained below in detail, the gas injector 132 may inject one or more process gases received from the gas distribution system 130 into the dome 102 during substrate processing. The gas injector 132 may inject one or more cleaning gases received from the gas distribution system 130 into the dome 102 during the cleaning process. The gas injector 132 comprises a ceramic material such as alumina.

The gas delivery system 130 comprises one or more gas sources 150-1, 150-2, . . . , and 150-N (collectively, the gas sources 150), where N is an integer greater than one. The gas sources 150 are connected by valves 152-1, 152-2, . . . , and 152-N (collectively, the valves 152) and mass flow controllers 154-1, 154-2, . . . , and 154-N (collectively, the mass flow controllers 154) to a manifold 156. The manifold 156 is connected to the gas injector 132. One or more of the gas sources 150 supply one or more process gases to the dome 102 via the manifold 156 and the gas injector 132 during substrate processing. One or more of the gas sources 150 supply one or more cleaning gases to the dome 102 via the manifold 156 and the gas injector 132 during the cleaning process as described below.

A coil 134 is arranged around the dome 102. The coil 134 is described below in detail. Briefly, the coil 134 may comprise a plurality of (e.g., 3 or more) turns. A first end of the coil 134 is grounded. A second end of the coil 134 is connected to an RF generating system 136.

The RF generating system 136 generates and outputs RF power to the coil 134. For example only, the RF generating system 136 may comprise an RF generator 138 that generates the RF power. The RF power is fed by a matching network 140 to the coil 134. The RF power supplied to the coil 134 ignites the gas or gases injected by the gas injector 132 into the dome 102 and generates a plasma 142 in the dome 102 (i.e., in the upper portion of the processing chamber 103). Accordingly, the processing chamber 103 does not use any remote plasma typically generated by a remote plasma source arranged external to the processing chamber 103. Instead, the plasma 142 is generated in-situ (i.e., in the dome 102 of the processing chamber 103) during both substrate processing and cleaning process.

The base portion 105 of the showerhead 104 comprises a first set of holes (also called radical holes as described above) 160-1, 160-2, . . . , and 160-N (collectively, the radical holes 160), where N is an integer greater than one. The radical holes 160 extend vertically from the top surface 162 of the base portion 105 of the showerhead 104 to a substrate-facing bottom surface 164 of the base portion 105 of the showerhead 104 (also called a faceplate 164). The radical holes 160 may be called a first plenum of the showerhead 104.

The showerhead 104 filters ions from the plasma 142 and passes radicals from the plasma 142 through the radical holes 160 into the second portion of the processing chamber 103. The radicals react with the precursors in the gap between the showerhead 104 and the pedestal 112, and a thin film is deposited on the substrate 114 using a process such as ALD. The open area provided by the radical holes 160 for the radicals to pass through the showerhead 104 and the density and pattern of the radical holes 160 and the precursor holes 172 provide near-zero radial and azimuthal non-uniformity in films deposited using the showerhead 104.

In addition, the base portion 105 of the showerhead 104 comprises a plenum 166 that is separate (disjoint) from the radical holes 160. The plenum 166 is not in fluid communication with the radical holes 160. The plenum 166 may be called a second plenum of the showerhead 104. The plenum 166 receives one or more precursor gases from a second gas delivery system 170 during substrate processing. The plenum 166 receives an inert gas from the second gas delivery system 170 during the cleaning process. The second gas delivery system 170 is described below in detail with reference to FIG. 3.

The base portion 105 of the showerhead 104 further comprises a second set of holes (also called precursor holes) 172-1, 172-2, . . . , and 172-N (collectively, the precursor holes 172), where N is an integer greater than one. The precursor holes 172 extend vertically from the plenum 166 through the base portion 105 and through the faceplate 164 of the showerhead 104. One or more precursor gases are supplied through the precursor holes 172 into the lower portion of the processing chamber during substrate process. The precursor holes 172 and the plenum 166 are not in fluid communication with the radical holes 160.

The radical holes 160 and the precursor holes 172 are cylindrical. The radical holes 160 are greater in diameter and length than the precursor holes 172. The radical holes 160 are tapered at the top end (i.e., on the side facing the dome 102). The total cross-sectional area of the radical holes 160 is optimized to filter ions from the plasma 142 and to pass only radicals from the plasma 142 through the showerhead 104 into the lower portion of the processing chamber 103 comprising the pedestal 112. A tunable gap between the faceplate 164 of the showerhead 104 and the top surface 116 of the pedestal 112 allows precise control of the micro-volume in ALD processes. Further, a narrow gap between the faceplate 164 of the showerhead 104 and the top surface 116 of the pedestal 112 prevents depletion of radicals in the micro-volume in the gap.

The outer wall 109-1 of the cylindrical portion 107 of the showerhead 104 does not directly contact the top plate of the processing chamber 103. Due to this feature and since the cylindrical portion 107 of the showerhead 104 extends vertically below the top surface 116 of the pedestal 112 on which the substrate 114 is arranged, the cylindrical portion 107 of the showerhead 104 provides a symmetric thermal boundary condition (i.e., a region of constant temperature) around the edge of the top surface 116 of the pedestal 112. Accordingly, the pedestal 112 can be moved vertically within (i.e., through the height of) the cylindrical portion 107 to adjust the gap between the showerhead 104 and the pedestal 112 without a significant change in the thermal boundary condition surrounding the edge of the top surface 116 of the pedestal 112, which is advantageous during substrate processing.

Further, the cylindrical portion 107 of the showerhead 104 also provides a constant constriction to gas flow around the edge of the top surface 116 of the pedestal 112 when the pedestal 112 is moved up or down within the cylindrical portion 107. This simplifies the process of controlling the micro-volume of gases in the gap between the showerhead 104 and the pedestal 112 since the gas flow conditions around the edge of the top surface 116 of the pedestal 112 remain constant because the cylindrical portion 107 surrounds and is in close proximity to the edge of the top surface 116 of the pedestal 112. Accordingly, the pedestal 112 can be moved vertically within (i.e., through the height of) the cylindrical portion 107 to adjust the gap between the showerhead 104 and the pedestal 112 without a significant change in gas flow conditions around the edge of the top surface 116 of the pedestal 112.

The base portion 105 of the showerhead 104 further comprises a plurality of grooves 168-1, 168-2, . . . , and 168-N (collectively, the grooves 168), where N is an integer greater than 1. The grooves 168 form a cooling channel (explained with reference to FIG. 3) through which a coolant flows. A fluid delivery system 180 supplies the coolant to the grooves 168 through an inlet in the base portion 105 of the showerhead 104.

One or more temperature sensors (not shown) may be disposed in the base portion 105 of the showerhead 104. The temperature sensors may be connected to a temperature controller 182. The temperature controller 182 may control the supply of the coolant from the fluid delivery system 180 to the grooves 168 to control the temperature of the showerhead 104, which receives heat from the pedestal 112 and the plasma 142. The coolant flows through the grooves 168 and controls the temperature of the showerhead 104. The temperature of the showerhead 104 is less than the temperature of the pedestal 112 during substrate processing and the cleaning process. The temperature controller 182 maintains the temperature of the showerhead 104 at a first preset temperature (e.g., 50 degrees Celsius) that is less than the temperature of the pedestal 112 (e.g., 550 degrees Celsius) during substrate processing and the cleaning process.

Further, the pedestal 112 may comprise one or more heaters 184, a cooling system that receives a coolant from the fluid delivery system 180, and one or more temperature sensors. The temperature controller 182 may be connected to the temperature sensors in the pedestal 112. The temperature controller 182 may control power supply to the heaters 184. The temperature controller 182 may control the supply of the coolant from the fluid delivery system 180 to the cooling system in the pedestal 112 to control the temperature of the pedestal 112. The temperature of the pedestal 112 is greater than the temperature of the showerhead 104 during substrate processing and the cleaning process. The temperature controller 182 maintains the temperature of the pedestal 112 at a second preset temperature (e.g., 550 degrees Celsius) that is greater than the temperature of the showerhead 104 (e.g., 50 degrees Celsius) during substrate processing and the cleaning process.

The processing chamber 103 further comprises an enclosure 125. The enclosure 125 is cylindrical. The enclosure 125 is mounted on top of the showerhead 104. Specifically, the enclosure 125 is mounted on the vertical portion 128 of the cylindrical component 124. The enclosure 125 is described below in detail with reference to FIG. 2. Briefly, the enclosure 125 encloses the dome 102 and the coil 134. The enclosure 125 comprises a plurality of fans (schematically shown in FIG. 2). The fans are arranged along sidewalls of the enclosure 125 in an azimuthally symmetric configuration to provide uniform cooling for the dome 102 and the coil 134 as described below in detail with reference to FIG. 2.

A valve 186 and a pump 188 control the pressure in the processing chamber 103. The pump 188 also evacuates reactants from the processing chamber 103 during substrate processing and the cleaning process. A system controller 190 controls the components of the substrate processing system 100 described above and below.

### SECTION 2: DOME, COIL, INJECTOR, AND ENCLOSURE

The dome 102, the coil 134, the gas injector (hereinafter the injector) 132, and the enclosure 125 are now described in detail with reference to FIGS. 1 and 2. As described above, the dome 102 is elliptical in shape and comprises a ceramic material such as alumina. The elliptical shape of the dome 102 is not a mere design choice. Rather, the elliptical shape of the dome 102 is selected after extensive experimentation because the elliptical shape significantly reduces plasma induced thermal stresses on the dome 102 compared to other shapes.

In addition, the number of turns of the coil 134 and the positioning of the coil 134 around the dome 102 are not a mere design choice either. Rather, the number of turns of the coil 134 and the positioning of the coil 134 around the dome 102 are designed specifically to improve thermal loading on the dome 102 and to improve the life of the dome 102. Additionally, the elliptical shape of the dome 102 and the number of turns and positioning of the coil 134 around the dome 102 are designed specifically to increase the volume of the plasma 142, increase the surface area of the dome 102 that is bombarded by ions (which reduces damage of the inner walls of the dome 102 compared to other shapes), and reduce the thermal stress load on the dome 102.

Further, as described above, the dome 102 and the injector 132 comprise a ceramic material such as alumina, which is also not a design choice. Other materials such as quartz etch away due to the plasma 142 generated during substrate processing and the cleaning process. Other materials such as quartz etch away due to corrosive cleaning gases (e.g., fluorine) and other harsh process chemistries used during substrate processing and the cleaning process and due to the ion bombardment from the plasma. Therefore, after extensive experimentation, instead of quartz, a ceramic material such as alumina, which has a low dielectric constant and which does not etch away in these harsh environments, is selected to construct the dome 102 and the injector 132. The ceramic material such as alumina enables using the dome 102 and the injector 132 to generate the plasma 142 in the dome 102 using process gases during substrate processing and using cleaning gases during the cleaning process.

Additionally, the inner walls of the dome 102 are coated (e.g., spray coated) with a material (e.g., yttria) that is highly resistant to plasma induced heat and corrosion. The coating on the inner walls of the dome 102 is shown at 111. The coating 111 (e.g., yttria) not only bonds well with alumina but also enhances the resistance of alumina to plasma induced heat and corrosion. Accordingly, the coating 111 further protects the inner walls of the dome 102 from damage due to ion bombardment from the plasma 142 and from the plasma induced thermal and chemical stresses.

Thus, the dome 102 and the injector 132 comprising the ceramic material such as alumina serve the dual purposes of enabling substrate processing and chamber cleaning using the in-situ plasma 142 generated using a wide range of harsh chemistries and also last longer than when these components are made of other materials such as quartz.

FIG. 2 schematically shows the enclosure 125. The enclosure 125 comprises fans schematically shown at 127-1, 127-2, . . . , 127-8 (collectively, the fans 127). While eight fans 127 are shown for example only, any number of fans can be used. For symmetry, the fans 127 may be even in number. As described above, the fans 127 are arranged along the sidewalls of the enclosure 125 in an azimuthally symmetric configuration. Specifically, the enclosure 125 is cylindrical. The fans 127 are located equidistantly from each other on a circle along the sidewalls of the enclosure 125. Further, the fans 127 are located at the same distance d from the top and bottom of the enclosure 125.

The fans 127 provide cooling for the dome 102 and the coil 134. The cooling provided by the fans symmetrically arranged in the enclosure 125 is also not a mere design choice. Rather, due to the azimuthally symmetric arrangement, which is selected after extensive experimentation, the fans 127 distribute heat uniformly throughout the dome 102 and improve thermal uniformity across the dome 102. Specifically, the azimuthally symmetric arrangement of the fans along the sidewalls of the enclosure 125 is designed to effectively dissipate heat during substrate processing, where power load is low, and during the cleaning process, where the power load is high. Thus, in addition to the elliptical shape of the dome 102 and the design of the coil 134 described above, which reduce the thermal stresses on the dome 102 as described above, the azimuthally symmetric arrangement of the fans in the enclosure 125 further reduces the thermal stresses on the dome 102.

In some examples, while not shown, the fans 127 may be staggered. For example, alternate fans 127 may lie on two different circles (e.g., first and second circles) along the sidewalls of the enclosure 125. The first circle may be at the same distance (e.g., first distance) from the top of the enclosure 125 as the second circle from the bottom of the enclosure 125. The distance between the two circles (e.g., second distance) may be the same as or different than the first distance. In each circle, the fans 127 may be equidistant from each other but positions of the fans 127 in the first circle may be staggered or offset relative to positions of the fans 127 in the second circle. In other examples, positions of the fans 127 in both circles may be vertically aligned with each other. In some examples, the fans 127 may be arranged in more than two circles using any arrangement described above. Any combination of the above arrangements may be used. Further, in some examples, in any of the above arrangements and combinations thereof, all the fans 127 may have the same cooling capacity while in other examples, at least some of the fans 127 may have different cooling capacity or capacities than others.

The designs of the dome 102, the coil 134, the injector 132, and the enclosure 125 with the fans 127 provide many advantages described above. In addition, as described above, conventional substrate processing systems not only use a remote plasma source, which is eliminated in the substrate processing system 100 by using in-situ plasma 142, but also require changing temperatures of the showerhead and the pedestal during the cleaning process relative to the temperatures used during substrate processing. Changing the temperatures before and after the cleaning process wastes time and reduces the production of processed substrates.

In contrast, due to the use of the in-situ plasma 142, which is generated in the dome 102 during both substrate processing and the cleaning process (using different gases and chemistries), the temperatures of the showerhead 104 and the pedestal 112 need not be changed between substrate processing and the cleaning process. Rather, the temperatures of the showerhead 104 and the pedestal 112 are maintained (i.e., the temperatures are unified or unchanged) during both substrate processing and the cleaning process. Unifying the temperatures of the showerhead 104 and the pedestal 112 during both substrate processing and the cleaning process allows seamless transitions between substrate processing and the cleaning process. Unifying the temperatures eliminates the time wasted and production lost due to the waiting period required in conventional substrate processing systems where the cleaning process cannot begin until first temperatures required for the cleaning process are reached, and subsequently the substrate processing cannot resume until second temperatures required for the cleaning process are reached.

### SECTION 3: MITIGATION OF SHOWERHEAD CONTAMINATION

Additionally, as described above, during the cleaning process, particles ejected (e.g., etched) from surfaces (e.g., the top surface 116) of the pedestal 112 tend to contaminate the showerhead 104. In the conventional cleaning process, a remotely generated cleaning plasma is introduced into the processing chamber between the showerhead and the pedestal, which requires a long time to clean the showerhead due to the reasons described above. Regardless, some particles may still remain in the showerhead. Accordingly, the showerhead needs to be requalified for use before substrates can be processed.

In contrast, in the substrate processing system 100, the remote plasma is not used at all. Instead, the cleaning gas is supplied through the injector 132 into the dome 102 and the plasma 142 is generated in-situ in the dome 102. Therefore, the plasma 142 first cleans the showerhead 104 and then cleans the pedestal 112. Since the plasma 142 first encounters the showerhead 104, the plasma 142 cleans the showerhead 104 more effectively than when the remote plasma is introduced between the showerhead and the pedestal in the conventional cleaning process.

Further, to mitigate the contamination of the showerhead 104 from the particles ejected (e.g., etched) from surfaces (e.g., the top surface 116) of the pedestal 112, the controller 190 controls the flow of the cleaning gases through the injector 132. For example, the cleaning gas can be supplied at a high flow rate and/or high pressure. The controlled flow of the cleaning gases through the injector 132 pushes the particles ejected (e.g., etched) from the surfaces of the pedestal 112 downwardly relative to the showerhead 104. Thus, the controlled flow of the cleaning gases through the injector 132 mitigates (suppresses) the contamination of the showerhead 104 from the particles ejected (e.g., etched) from the surfaces of the pedestal 112.

Furthermore, since the injector 132 comprises the ceramic material such as alumina, the injector 132 is capable of handling (i.e., is not damaged by) the additional corrosive stresses imposed on the injector 132 by the high flow of the cleaning gases. Unifying the temperatures of the showerhead 104 and the pedestal 112 during substrate processing and the cleaning process requires that the pedestal 112 is maintained at the same high temperature during the cleaning process as during substrate processing. The high temperature of the pedestal 112 causes more particles to eject (e.g., etch) from the surfaces of the pedestal 112, which can contaminate the showerhead 104 without the high flow of the cleaning gases through the injector 132. Controlling the flow of the cleaning gases through the injector 132 suppresses the contamination of the showerhead 104 from the particles ejected (e.g., etched) from the surfaces of the pedestal 112 as described above.

Accordingly, the capability of the injector 132, which is constructed using the ceramic material such as alumina, of handling the additional corrosive stresses imposed by the high flow of the cleaning gases allows maintaining the temperature of the pedestal 112 at the same high temperature as the temperature used during substrate processing without contaminating the showerhead 104. Although the high temperature of the pedestal 112 causes more particles to ejected (e.g., etched) from the surfaces of the pedestal 112, the high flow of the cleaning gases through the injector 132 suppresses the contamination of the showerhead 104 from the particles ejected (e.g., etched) from the surfaces of the pedestal 112. Thus, controlling the flow of the cleaning gases through the injector 132 allows unifying the temperatures during substrate processing and the cleaning process.

While controlling the flow of the cleaning gases through the injector 132 mitigates the particle contamination problem, the showerhead 104 may remain contaminated due to any residual traces of the cleaning gases that can be trapped and stagnate in the plenum 166 and the holes 160, 172 of the showerhead 104. The second gas delivery system 170 helps further mitigate the particle contamination problem as described below with reference to FIG. 3. The second gas delivery system 170 also mitigates contamination of the showerhead 104 due to stagnant cleaning gases that can remain trapped in the plenum 166 and the holes 172 of the showerhead 104 as follows.

FIG. 3 shows the second gas delivery system 170 in further detail. While shown separately, the second gas delivery system 170 can be part of the second gas delivery system 130. The second gas delivery system 170 may be similar to the second gas delivery system 130. The substrate processing system 100 further comprises valves 174, 176 and a manifold 178 connected to the second gas delivery system 170 and the plenum 166 of the showerhead 104 as shown. The second gas delivery system 170 is connected to the plenum 166 of the showerhead 104 via the valves 174, 176 and the manifold 178. The valves 174, 176 are connected to the second gas delivery system 170 and to the manifold 178 as shown.

The valve 174 is connected one or more gas sources in the second gas delivery system 170 that supply one or more precursor gases. While a single valve 174 is shown, a plurality of valves may be respectively connected to a plurality of gas sources in the second gas delivery system 170 that supply a plurality of precursor gases. The plurality of valves can be controlled in the same manner as the valve 174, which is described below. The valve 176 is connected to a gas source in the second gas delivery system 170 that supplies an inert gas. The controller 190 controls the valves 174, 176 as follows.

During substrate processing, the controller 190 opens the valve 174 and closes the valve 176. Accordingly, the second gas delivery system 170 supplies one or more precursor gases to the plenum 166 of the showerhead 104 via the valve 174 and the plenum 178 during substrate processing.

During the cleaning process, the controller 190 closes the valve 174 and opens the valve 176. The second gas delivery system 170 supplies an inert gas to the plenum 166 of the showerhead 104 via the valve 176 and the plenum 178 during the cleaning process. The inert gas is supplied at a low rate as a trickle. The flow of the inert gas at the low rate through the showerhead 104 serves two purposes.

First, the flow of the inert gas suppresses backflow (i.e., flow of any material comprising the particles ejected (e.g., etched) from the surfaces of the pedestal 112) into the showerhead 104 and the dome 102. Essentially, the flow of the inert gas suppresses backflow of any material from the lower portion of the processing chamber 103 to the upper portion of the processing chamber 103. Second, the flow of the inert gas removes any stagnant cleaning gases that can otherwise remain trapped in the plenum 166 and the holes 160, 172 of the showerhead 104.

Thus, during the cleaning process, the controlled flow of the cleaning gases through the injector 132 and the flow of the inert gas at the low rate through the showerhead 104 significantly alleviate and/or eliminate the contamination of the showerhead 104 due to the particles ejected (e.g., etched) from the surfaces of the pedestal 112 and any stagnant cleaning gases that can otherwise remain trapped in the plenum 166 and the holes 160, 172 of the showerhead 104.

Accordingly, the elliptical shape, the ceramic material, and the coating 111 of the dome 102 reduce the thermal loading on the dome 102 and etching of the inner walls of the dome 102. The design of the coil 134 further reduces the thermal loading on the dome 102 and increases the plasma volume in the dome 102. The injector 132 comprising the ceramic material sustains the high flow of corrosive cleaning gas that suppresses particle contamination of the showerhead 104. The inert gas flow through the showerhead 104 further reduces contamination of the showerhead 104 by preventing cleaning gas stagnation in the showerhead. The controlled flow of the cleaning gases through the injector 132 and the flow of the inert gas through the showerhead 104 eliminate the contamination of the showerhead 104 due to the particles ejected (e.g., etched) from the surfaces of the pedestal 112 and any stagnant cleaning gases that can otherwise remain trapped in the showerhead 104. The enclosure 125 with fans 127 improve the thermal uniformity on the dome 102.

The above features enable generating in-situ cleaning plasma while unifying temperatures of the showerhead 104 and the pedestal 112 and reduce thermal loading on the dome 102 during substrate processing and chamber cleaning. Thus, using in-situ cleaning plasma and unifying the temperatures of the showerhead 104 and the pedestal 112 and reducing thermal loading on the dome 102 during substrate processing and the cleaning process increases the life of the dome 102. Using in-situ cleaning plasma and unifying the temperatures of the showerhead 104 and the pedestal 112 improves the cleaning process. Unifying the temperatures of the showerhead 104 and the pedestal 112 eliminates delays that are otherwise necessitated by temperature transitions between substrate processing and the cleaning process, which increases the productivity of the tool.

### SECTION 4: METHOD OF SUBSTRATE PROCESSING AND CHAMBER CLEANING

FIG. 4 shows a method 200 for processing substrates and cleaning the processing chamber 103 according to the present disclosure. The method 200 is also a method of operating the substrate processing system 100. For example, the controller 190 performs the method 200 and controls the elements of the substrate processing system 100 according to the method 200.

At 202, the method 200 determines if the time to process the substrate has arrived. For example, the method 200 determines if the substrate 114 is loaded into the processing chamber 103 and the gap between the substrate 114 and the showerhead 104 is adjusted as required by the process (e.g., ALD) to be used to process the substrate 114. If the time to process the substrate has arrived, at 204, the method 200 heats the pedestal 112 and the showerhead 104 to the temperatures required by the process (e.g., ALD) to be performed on the substrate 114. In some processes, the pedestal 112 and the showerhead 104 may be preheated to the temperatures required by the processes. At 206, the method 200 supplies one or more process gases to the injector 132 and optionally, depending on process requirements, one or more precursors to the showerhead 104. At 208, the method 200 supplies RF power to the coil 134 to strike the plasma 142 (if used) in the dome 102.

At 210, the method determines if the time to clean the processing chamber 103 (e.g., time to perform a periodic preventive maintenance of the processing chamber 103) has arrived. If the processing chamber 103 need not be cleaned, at 212, the method 200 continues processing substrates (e.g., the same or a new substrate), and the method 200 returns to 206. If the processing chamber 103 to be cleaned, at 214, the method 200 maintains the temperatures of the pedestal 112 and the showerhead 104 at the same temperatures as the temperatures used at 204 for processing the substrates in 206 and 208. The method 200 does not change the temperatures of the pedestal 112 and the showerhead 104. The method 200 removes the substrate 114 from the processing chamber 103 and lowers the pedestal 112 relative to the showerhead 104.

At 216, the method 200 stops the flow of the process and precursor gases to the injector 132 and the showerhead 104 and stops the RF supply if used at 208. At 218, the method 200 supplies one or more cleaning gases (e.g., a cleaning gas or a mixture of cleaning gases or other cleaning chemistries) to the injector 132 and supplies an inert gas from the second gas delivery system 120 directly to the showerhead 104. At 220, the method 200 supplies RF power to the coil 134 to strike in-situ cleaning plasma in the dome 102. The method 200 also controls the flow of the one or more cleaning gases through the injector 132 and the flow of the inert gas through showerhead 104 as described above.

At 222, the method determines if the time to stop the cleaning process has arrived (i.e., if chamber cleaning is complete). The method 200 returns to 218 and continues the cleaning process at 218 and 220 if the time to stop the cleaning process has not arrived (i.e., if chamber cleaning is incomplete). If the time to stop the cleaning process has arrived, at 224, the method 200 stops the flow of the one or more cleaning gases to the injector 132, stops the flow of the inert gas to the showerhead 104, and stops the RF supply to the coil 134. At 226, the method 200 maintains the temperatures of the pedestal 112 and the showerhead 104 used during the cleaning process in 218 and 220, which are the same temperatures used for processing the substrates in 206 and 208. The method 200 does not change the temperatures of the pedestal 112 and the showerhead 104. Subsequently, at 212, the method 200 continues processing substrates (e.g., a new substrate) without delay since the pedestal 112 and the showerhead 104 are already at the temperatures used for processing the substrates in 206 and 208.

The predetermined range described above is now explained in further detail. For example, a process (e.g., ALD) may require the temperatures of the showerhead 104 and the pedestal 112 to be 50 and 550 degrees Celsius to process substrates, respectively. These temperatures of the showerhead 104 and the pedestal 112 at which a process processes substrates may be called the predetermined temperatures of the showerhead 104 and the pedestal 112 for the process.

The temperature controller 182 tightly controls the temperatures of these components as described above with reference to FIG. 1. However, in some instances, at the beginning of the cleaning process, these temperatures may slightly vary and may not be exactly the same as the temperatures used during substrate processing. However, the variation is slight and is tightly controlled within the predetermined range, which may be as narrow as 0-1% of the predetermined temperatures.

For example, suppose that the process (e.g., ALD) requires the temperatures of the showerhead 104 and the pedestal 112 to be 50 and 550 degrees Celsius to process substrates, respectively. At the beginning of the cleaning process, the temperature of the showerhead 104 may differ from 50 degrees Celsius by 0-1%, and the temperature of the pedestal 112 may differ from 550 degrees Celsius by 0-1%. The temperature controller 182 can sense the variation using the temperature sensors in the showerhead 104 and the pedestal 112. Based on the sensed variation, the temperature controller 182 can control one or more of the heater 184 in the pedestal 112 and the coolant supplied to the showerhead 104 and the pedestal 112 to quickly bring these temperatures back to the respective predetermined temperatures. A similar procedure can be used after the cleaning process ends and at the beginning of processing a new substrate using the process (e.g., ALD).

Thus, for a given process, the temperatures of these components are essentially maintained close to or substantially equal to the temperatures required by the process within a narrow, predetermined range (e.g., 0-1%) during substrate processing and the cleaning process. Accordingly, after the cleaning process, substrate processing can resume quickly without the long delay typically required to allow the temperatures of the components to transition from a first set of temperatures used for the cleaning process to a second, widely different set of temperatures typically used by the process for processing substrates. Additionally, the temperature controller 182 can maintain the temperatures of the showerhead 104 and the pedestal 112 the same without variation (i.e., unchanged) during substrate processing and the cleaning process. Accordingly, after the cleaning process, substrate processing can resume immediately without any delay typically required to allow the temperatures of the components to transition from a first set of temperatures used for the cleaning process to a second, widely different set of temperatures typically used by the process for processing substrates.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.” In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a processing chamber comprising a first portion and a second portion, the first portion comprising a dome, the dome comprising a ceramic material and being elliptical in shape;
a pedestal configured to process a substrate arranged in the second portion of the processing chamber;
a showerhead arranged at a base of the dome between the first and second portions of the processing chamber;
an injector comprising the ceramic material mounted on the dome and configured to inject a process gas and a cleaning gas into the dome during substrate processing and cleaning of the processing chamber, respectively;
a coil disposed around a portion of the dome;
a radio frequency (RF) generator configured to supply RF power to the coil to generate plasma in the dome during the substrate processing and the cleaning of the processing chamber; and
a controller configured to control temperatures of the pedestal and the showerhead at respective predetermined temperatures within a predetermined range during the substrate processing and the cleaning of the processing chamber.

2. The substrate processing system of claim 1 wherein the predetermined range is 0-1% of the respective predetermined temperatures.

3. The substrate processing system of claim 1 wherein the controller is configured to maintain the temperatures of the pedestal and the showerhead unchanged at the respective predetermined temperatures during the substrate processing and the cleaning of the processing chamber.

4. The substrate processing system of claim 1 wherein the ceramic material is alumina.

5. The substrate processing system of claim 1 wherein inner walls of the dome are coated with a second material that is resistant to heat and corrosion.

6. The substrate processing system of claim 5 wherein the second material is yttria.

7. The substrate processing system of claim 1 further comprising an enclosure that is arranged around the dome and the coil and that is attached to a periphery of the showerhead, the enclosure comprising a plurality of fans arranged azimuthally symmetrically along sidewalls of the enclosure.

8. The substrate processing system of claim 1 further comprising a gas delivery system configured to supply the cleaning gas through the injector at a rate that suppresses particles ejected from the pedestal from contaminating the showerhead during the cleaning of the processing chamber.

9. The substrate processing system of claim 1 further comprising a gas delivery system configured to supply an inert gas directly to the showerhead to suppress particles ejected from the pedestal from contaminating the showerhead during the cleaning of the processing chamber.

10. The substrate processing system of claim 1 further comprising a gas delivery system configured to supply an inert gas directly to the showerhead to prevent the cleaning gas from stagnating in the showerhead after the cleaning of the processing chamber.

11. The substrate processing system of claim 1 further comprising a gas delivery system, wherein the showerhead comprises:
a first plenum configured to filter ions and pass radicals from the plasma to the second portion of the processing chamber; and
a second plenum configured to (i) directly receive a precursor from the gas delivery system and supply the precursor to the second portion of the processing chamber during the substrate processing and (ii) directly receive an inert gas from the gas delivery system during the cleaning of the processing chamber.

12. The substrate processing system of claim 1 wherein the coil comprises a number of turns and wherein the number of turns and locations of the turns around the dome distribute ions and thermal load from the plasma throughout the dome.

13. The substrate processing system of claim 1 wherein the pedestal comprises a heater, the substrate processing system further comprising:
a fluid delivery system configured to supply a coolant to the pedestal and the showerhead;
wherein the controller is configured to control the heater and flow of the coolant to maintain the temperatures of the showerhead and the pedestal within the predetermined range of the respective predetermined temperatures during the substrate processing and the cleaning of the processing chamber.

14. The substrate processing system of claim 1 wherein the pedestal comprises a heater, the substrate processing system further comprising:
a fluid delivery system configured to supply a coolant to the pedestal and the showerhead;
wherein the controller is configured to control the heater and flow of the coolant to maintain the temperatures of the pedestal and the showerhead unchanged at the respective predetermined temperatures during the substrate processing and the cleaning of the processing chamber.

15. A method of cleaning a processing chamber comprising a pedestal and a showerhead configured to process a substrate, the method comprising:
controlling, during the cleaning of the processing chamber, temperatures of the pedestal and the showerhead within a predetermined range of respective predetermined temperatures used during processing of the substrate;
supplying a cleaning gas into an elliptical dome of the processing chamber though an injector mounted on the elliptical dome, the elliptical dome and the injector comprising a ceramic material;
generating a plasma in the elliptical dome by supplying radio frequency (RF) power to a coil disposed around the elliptical dome; and
controlling flow of the cleaning gas through the injector to suppress contamination of the showerhead due to particles ejected from the pedestal.

16. The method of claim 15 wherein the predetermined range is 0-1% of the respective predetermined temperatures.

17. The method of claim 15 further comprising maintaining the temperatures of the pedestal and the showerhead unchanged at the respective predetermined temperatures during the processing of the substrate and the cleaning of the processing chamber.

18. The method of claim 15 further comprising spray coating inner walls of the elliptical dome with a second material that is resistant to heat and corrosion.

19. The method of claim 18 wherein the ceramic material is alumina and the second material is yttria.

20. The method of claim 15 further comprising:
enclosing the elliptical dome and the coil in an enclosure attached to a periphery of the showerhead; and
cooling the elliptical dome using a plurality of fans arranged azimuthally symmetrically along sidewalls of the enclosure.

21. The method of claim 15 further comprising supplying an inert gas directly to the showerhead to further suppress the contamination of the showerhead due to the particles.

22. The method of claim 15 further comprising flowing an inert gas through the showerhead to prevent the cleaning gas from stagnating in the showerhead.

23. The method of claim 15 further comprising arranging turns of the coil around the elliptical dome to distribute ions and thermal load from the plasma throughout the elliptical dome.

24. The method of claim 15 further comprising, after the cleaning of the processing chamber:
stopping supply of the cleaning gas and the RF power;
controlling the temperatures of the pedestal and the showerhead within the predetermined range of the respective predetermined temperatures; and
supplying a process gas into the elliptical dome though the injector to process a second substrate in the processing chamber.

25. The method of claim 24 further comprising supplying a precursor directly to the showerhead.

26. The method of claim 24 further comprising:
striking a second plasma in the elliptical dome by supplying the RF power to the coil; and
filtering ions and passing radicals from the second plasma to the second substrate.

27. The method of claim 24 further comprising supplying a coolant through the pedestal and the showerhead to maintain the temperatures of the showerhead and the pedestal within the predetermined range of the respective predetermined temperatures during the processing of the second substrate in the processing chamber.

28. The method of claim 24 further comprising supplying a coolant through the pedestal and the showerhead to maintain the temperatures of the pedestal and the showerhead unchanged at the respective predetermined temperatures during the processing of the second substrate in the processing chamber.
